(19) United States
(12) Patent Application Publication
(10) Pub. No.: US 2024/0023301 A1
(43) Pub. Date: Jan. 18, 2024

(54) ELECTROMAGNETICALLY COMPATIBLE HOUSING DEVICE

(71) Applicant: Vitesco Technologies GmbH, Regensburg (DE)

(72) Inventors: Markus Christoph, München (DE); Stefan Kulzer, München (DE)

(21) Appl. No.: 18/220,385

(22) Filed: Jul. 11, 2023

(30) Foreign Application Priority Data
Jul. 13, 2022 (DE) 10 2022 207 140.9

(51) Int. Cl. H05K 9/00; H01M 50/202; H01M 50/249; H01M 50/24; H01M 50/296; H01M 50/224; B60L 50/64

(52) U.S. Cl. CPC H05K 9/0049; H01M 50/202; H01M 50/249; H01M 50/24; H01M 50/296; H01M 50/224; B60L 50/64; H01M 2220/20

(57) ABSTRACT

An electromagnetically compatible housing device for a high-voltage battery of a vehicle, having: a first housing part which shields electromagnetic radiation and has an electrically conducting contact face, and a second housing part which is in the form of a spring part and shields electromagnetic radiation and which is connected in an electrically conducting manner to the electrically conducting contact face of the first housing part and is configured to establish electrically conducting contact with a battery housing part of the high-voltage battery.

### CROSS REFERENCE TO RELATED APPLICATIONS

This application claims priority to German Patent Application No. 10 2022 207 140.9, filed Jul. 13, 2022, the contents of such application being incorporated by reference herein.

### FIELD OF THE INVENTION

The invention relates to an electromagnetically compatible housing device, EMC housing device for short, and in particular to an EMC housing device for a high-voltage battery of a vehicle.

### BACKGROUND OF THE INVENTION

Modern battery-operated vehicles usually have a battery, in particular a high-voltage battery, which must be electrically contacted, for example by an on-board charging system in the vehicle. It is important that electromagnetic radiation, which may interfere with electromechanical or electronic components, is blocked as far as possible. Such shielding is generally effected by a metal housing. However, metal housings are not very flexible and can therefore compensate for any tolerances in the vehicle to only a limited extent.

### SUMMARY OF THE INVENTION

An aspect of the present invention is an electromagnetically compatible housing device (EMC housing device), in particular for a high-voltage battery of a vehicle, which has a technically simple design and additionally offers sufficiently great tolerance compensation.

The electromagnetically compatible housing device according to an aspect of the invention serves in particular as a housing device for a high-voltage battery of a vehicle and has the following components: a first housing part which shields electromagnetic radiation and has an electrically conducting contact face, and a second housing part which is in the form of a spring part and shields electromagnetic radiation and which is connected in an electrically conducting manner to the electrically conducting contact face of the first housing part and is configured to establish electrically conducting contact with a battery housing part of the high-voltage battery.

An aspect of the invention is based at least in part on the finding that, in particular in the case of battery-operated vehicles, the installation site and/or the site of the electrical connection to the high-voltage battery of the vehicle can vary greatly depending on the type and model of the vehicle. It may further be that, in the context of the electrical connection to the high-voltage battery of the vehicle, electromagnetic interfering signals may occur, which in some circumstances can impair the proper functioning of the high-voltage battery and/or of other electronic elements of the vehicle. An aspect of the present invention is therefore based at least in part on the finding that an electromagnetically compatible housing, or housing device, must be created, which on the one hand can permit electrical connection over a large tolerance range and on the other hand ensures sufficiently high shielding against electromagnetic interfering signals. The housing device according to an aspect of the invention is further based at least in part on the finding that such a modular housing is achieved, for example, in that the housing device first has a first housing part which shields electromagnetic radiation and which cooperates with a second housing part, which is in the form of a spring part and likewise shields electromagnetic radiation, such that, through electrical contact with a battery housing part of the high-voltage battery, an accommodation space that shields electromagnetic radiation is ultimately created. This accommodation space shielding electromagnetic radiation acts, as it were, like a Faraday cage. As a result, it is possible to sufficiently shield electromechanical components, such as, for example, a busbar, or electronic elements, such as, for example, electronic components, interconnect devices or the like, which may be arranged inside the housing device and can produce electromagnetic interfering signals. This is relevant in particular for the use of on-board charging systems in the vehicle, which generally have electromechanical and also electronic elements which can act as sources of electromagnetic interference in the vehicle.

Because the second housing part is additionally in the form of a spring part and thus permits a certain flexibility for connection to the battery housing part of the high-voltage battery, any tolerances which may be present in the vehicle can be maintained.

According to a preferred configuration of the housing device according to an aspect of the invention, the second housing part is an electrically conducting sheet-metal part. Sheet-metal parts are inexpensive to produce and have a comparatively low weight.

A particularly preferred configuration thus provides that the sheet-metal part is in one piece. This facilitates the installation, since fewer individual parts are necessary on assembly of the housing device.

It is further particularly preferred that the sheet-metal part is a stamped part. The shape of the second housing part can thus readily be adapted to the geometry required in a particular case.

A further preferred configuration provides that the second housing part has on a first side, which faces the electrically conducting contact face of the first housing part, first spring contact elements for contacting the electrically conducting contact face of the first housing part. Because the second housing part has on its first side first spring contact elements for contacting the electrically conducting contact face of the first housing part, no screw connections or the like are necessary for establishing an electrical connection between the first housing part and the second housing part. This permits more flexibility in the connection of the housing device, whereby the field of application of the housing device according to an aspect of the invention can be widened.

It is particularly preferred if the second housing part has on a second side opposite the first side second spring contact elements for contacting the battery housing part. Here too, the second spring contact elements act as tolerance compensation for the electrical contacting of the battery housing part.

It is further preferred if the electrically conducting contact face of the first housing part has web portions formed in some regions, which web portions are in electrically conducting contact with the first spring contact elements. The web portions formed on the first housing part can in particular be web portions formed in one piece. The web portions increase a contact face on the first housing part. The web portions project in the direction toward the second housing part and serve for the electrical connection of the first spring contact elements of the second housing part.

It is particularly preferred if the first spring contact elements contact the web portions laterally. Lateral contacting permits relative displacement of the first and second housing parts within certain limits and can therefore serve as tolerance compensation.

It is particularly preferred if the first spring contact elements are in the form of clamp elements which contact the web portions on opposite sides. This particularly preferred configuration constitutes an additional tolerance compensation, since the second housing part can be moved within certain limits not only in the direction of longitudinal extent of the web portions but also transverse to the direction of longitudinal extent of the web portions without the electrical contact between the first spring contact elements and the web portions being impaired. The electrical contacting of the web portions on opposite sides additionally has the effect that the clamp elements lie against the web portions on two sides and the web portions thus perform a certain guiding function for guiding the clamp elements, in particular for the case where a translational displacement takes place between the first housing part and the second housing part.

A further preferred configuration provides that the first housing part is a die-cast part and the web portions are formed by a die-casting process. As a result, the first housing part can be produced in one piece and can readily be adapted to corresponding geometries.

### BRIEF DESCRIPTION OF THE DRAWINGS

Further features and aspects of the present invention will become apparent to a person skilled in the art by practising the present teaching and taking into consideration the accompanying drawings. In the figures:

FIG. 1 shows a schematic view in section of a configuration of an electromagnetically compatible housing device according to an aspect of the invention which is fastened to a battery housing part of a high-voltage battery of a vehicle, and

FIG. 2 shows a schematic detail view of a second housing part, in the form of a spring part, of the housing device according to an aspect of the invention of FIG. 1.

Elements of the same design or function are provided with the same reference signs throughout the figures.

### DETAILED DESCRIPTION OF THE PREFERRED EMBODIMENTS

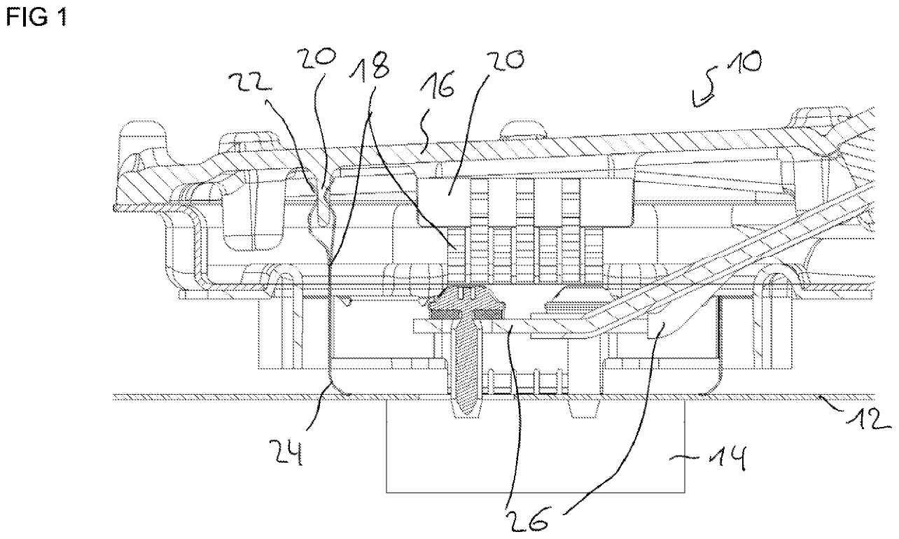

Reference is made first to FIG. 1, which shows a schematic view in section of an electromagnetically compatible housing device 10. The housing device 10 serves to ensure a certain electromagnetic compatibility, which is frequently required in particular in vehicles. The housing device 10 is fastened in an electrically conducting manner to a battery housing part 12 of a high-voltage battery 14. The high-voltage battery 14 may be a traction battery of a battery-operated vehicle, for example.

The electromagnetically compatible housing device 10 has a first housing part 16 which shields electromagnetic radiation. The first housing part 16 can be electrically conducting, for example, but at least has electrically conducting contact faces for a second housing part 18, which is in the form of a spring part and likewise shields electromagnetic radiation. The second housing part 18 is in electrically conducting contact with the electrically conducting contact faces of the first housing part 16. In the concrete example of FIG. 1, the first housing part 16 is a die-cast part which has web portions 20 formed by means of a die-casting process. The web portions 20 are thus formed in one piece on the first housing part 16 and extend in the direction toward the second housing part 18.

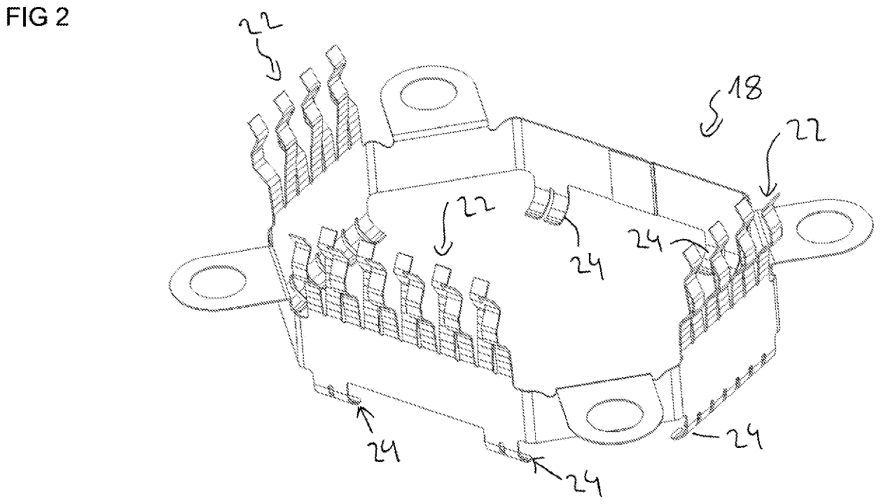

The second housing part 18, which will be described in greater detail in connection with FIG. 2, engages laterally around the web portions 20 by means of first spring contact elements 22 in the form of clamp elements. The first spring contact elements 22 in the form of clamp elements contact the web elements 20 laterally on opposite sides and, by lying laterally against the web portions 20, establish an electrically conducting connection with the first housing part 16.

The second housing part 18 is in particular in the form of a one-piece, stamped sheet-metal part and is adapted to the geometry in question.

The second housing part 18 has on a side facing the battery housing part 12 second spring contact elements 24, which are in electrically conducting contact with the battery housing part 12. The first housing part 16, together with the second housing part 18 and the battery housing part 12, forms a common accommodation space for accommodating electromechanical elements or electronic elements, which may be arranged in the accommodation space. By way of example, there are shown inside the accommodation space in FIG. 1 busbars 26, for example, which are to be electrically connected to the high-voltage battery 14 and can be an example of electromechanical elements. It is further conceivable that electronic elements such as, for example, electronic components, interconnect devices or the like, as would be necessary for an on-board charging system, for example, are also located in the accommodation space.

Reference is now made to FIG. 2, which shows a schematic detail view of the second housing part 18 in the form of a spring part.

As can be seen in FIG. 2, the second housing part 18 is a stamped part which has the first spring contact elements 22 in the form of clamp elements which have already been described and the second spring contact elements 24 on an opposite side. The number and arrangement of the spring contact elements 22, 24 can be adapted to the geometry in question and to the requirement in question. In other configurations (not shown) of the second housing part 18 and of the first housing part 16, the first and second housing parts 16, 18 can therefore have other expedient shapes and geometries. What is important is that the second housing part 18 has on a side facing the first housing part 16 the spring contact elements 22 in the form of clamp elements for contacting, in particular laterally, the web portions 20 and has on a side opposite the first spring contact elements 22 second spring contact elements 24 which are configured for electrically contacting the battery housing part 12.

1. An electromagnetically compatible housing device for a high-voltage battery of a vehicle, having:
a first housing part which shields electromagnetic radiation and has an electrically conducting contact face, and
a second housing part which is in the form of a spring part and shields electromagnetic radiation and which is connected in an electrically conducting manner to the electrically conducting contact face of the first housing part and is configured to establish electrically conducting contact with a battery housing part of the high-voltage battery.

2. The housing device as claimed in claim 1, wherein the second housing part is an electrically conducting sheet-metal part.

3. The housing device as claimed in claim 2, wherein the sheet-metal part is in one piece.

4. The housing device as claimed in claim 3, wherein the sheet-metal part is a stamped part.

5. The housing device as claimed in claim 1, wherein the second housing part has on a first side, which faces the electrically conducting contact face of the first housing part, first spring contact elements for contacting the contact face.

6. The housing device as claimed in claim 5, wherein the second housing part has on a second side opposite the first side second spring contact elements for contacting the battery housing part.

7. The housing device as claimed in claim 5, wherein the electrically conducting contact face of the first housing part has web portions formed in some regions, which web portions are in electrically conducting contact with the first spring contact elements.

8. The housing device as claimed in claim 7, wherein the first spring contact elements contact the web portions laterally.

9. The housing device as claimed in claim 8, wherein the first spring contact elements are in the form of clamp elements which contact the web portions on opposite sides.

20. The housing device as claimed in claim 1, wherein the first housing part is a die-cast part and the web portions are formed by a die-casting process.
